(19) United States
(12) Patent Application Publication
(10) Pub. No.: US 2023/0195983 A1
(43) Pub. Date: Jun. 22, 2023

(54) HYPER-CONVERGED INFRASTRUCTURE (HCI) PLATFORM DEVELOPMENT WITH SMARTNIC-BASED HARDWARE SIMULATION

(71) Applicant: Dell Products L.P., Round Rock, TX (US)

(72) Inventors: Ciel Jinfeng LI, Shanghai (CN); Tianhe LI, Shanghai (CN); Shufang JI, Shanghai (CN); Joan Jun XIONG, Shanghai (CN)

(73) Assignee: Dell Products L.P., Round Rock, TX (US)

(21) Appl. No.: 17/568,481

(22) Filed: Jan. 4, 2022

(30) Foreign Application Priority Data
Dec. 21, 2021 (CN) 202111569521.5

(51) Int. Cl. G06F 30/331; G06F 13/12; G06F 9/54

(52) U.S. Cl. CPC G06F 30/331; G06F 13/122; G06F 9/541; G06F 2213/3808

(57) ABSTRACT

A platform development system and method in which configuration information for an information handling resource type, e.g., a network interface card, is obtained by accessing a first instance of the resource type. The configuration information includes one or more fixed elements and a corresponding number of variable elements. Configuration information may include attribute-value pairs in which the attribute field of each pair is the fixed part of the configuration information and the corresponding value field is the variable part. A simulation policy, indicative of the fixed part of the configuration information, may then be defined for the resource type of interest. The simulation policy, in conjunction with user-specified values for the variable part of the configuration information, may define configuration information for a second instance of the resource type. A management server simulator may then simulate the second instance of the resource type based on the applicable configuration information.

### TECHNICAL FIELD

The present disclosure relates to platform development and, more specifically, developing platforms for distributed computing systems including HCI platforms.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

HCI platform development has traditionally been performed on server machines with fully-provisioned hardware. Often, however, it may be expensive, time consuming, and/or otherwise impracticable for a platform developer to obtain hardware instances for all significant device types that an HCI platform might support including, without limitation, network interface cards (NICs), solid state drives (SSDs), central processing units (CPUs), different models of storage disks, and even different models of physical servers. This is especially true for new or recently released hardware devices, which may be precisely where platform development is of most value. In addition, platform development may including subjecting resources to marginal, anomalous, and/or critical states or conditions that may be difficult to establish and that may result to degradation or destruction of physical resources.

### SUMMARY

In accordance with teachings disclosed herein, common problems associated with HCI platform development are addressed by a platform development system and method in which configuration information for an information handling resource type, such as a network interface card, a storage resource, a processing resource, or the like, is obtained by accessing a first instance of the resource type. The configuration information indicates or includes one or more fixed elements and one or more variable elements.

In at least one embodiment, the configuration information may include one or more attribute-value pairs wherein the attribute field of each pair is the fixed part of the configuration information and the corresponding value field is the variable part of the configuration information. In the case of a NIC resource type, for example, the configuration information may comprise a set of three attribute value pairs including a first attribute value pair indicative of a vendor, a second attribute value pair indicative of a model, and a third attribute value pair indicative of a firmware version. In this example, the fixed part of the configuration information includes the attributes, i.e., vendor, model, and firmware version.

A simulation policy, indicative of the fixed part of the configuration information, may then be defined for the resource type of interest. The simulation policy, in conjunction with user-specified values for the variable part of the configuration information, may be suitable and sufficient to define configuration information for a second instance of the resource type. Disclosed methods may further include providing a management server simulator to simulate the second instance of the resource type in accordance with the applicable configuration information.

The configuration information may be obtained by a baseboard management controller (BMC) communicatively coupled to the first instance of the information handling resource type. The information handling resource type may be any one of a plurality of information handling resource types including, as non-limiting examples, a network interface card (NIC) type, a storage device type, and a central processing unit (CPU) type.

In at least one embodiment, the management server simulator is implemented as a Redfish simulator configured to provide Redfish services. Redfish refers to a suite of specifications for an industry standard protocol providing a RESTful interface for managing servers, storage, networking, and converged infrastructure. The Redfish simulator may include one or more simulator application programming interfaces (APIs) configured to receive requests from a Redfish client and further configured to inject user-specified values for the variable elements into responses provided to the Redfish client. The management server simulator may implemented as a SmartNIC installed on a physical node and communicatively coupled to a baseboard management controller.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of a hyper-converged infrastructure (HCI) environment include one or more HCI clusters, each of which may include one or more HCI nodes;

FIG. 2 illustrates elements of an HCI node;

FIG. 3 illustrate an exemplary information handling system;

FIG. 4 illustrates a flow diagram of a platform development method in accordance with disclosed teachings;

FIG. 5 is a block diagram representation of at least some hardware and/or software elements of disclosed systems;

FIG. 6 is a block diagram representation of at least some software elements.

### DETAILED DESCRIPTION

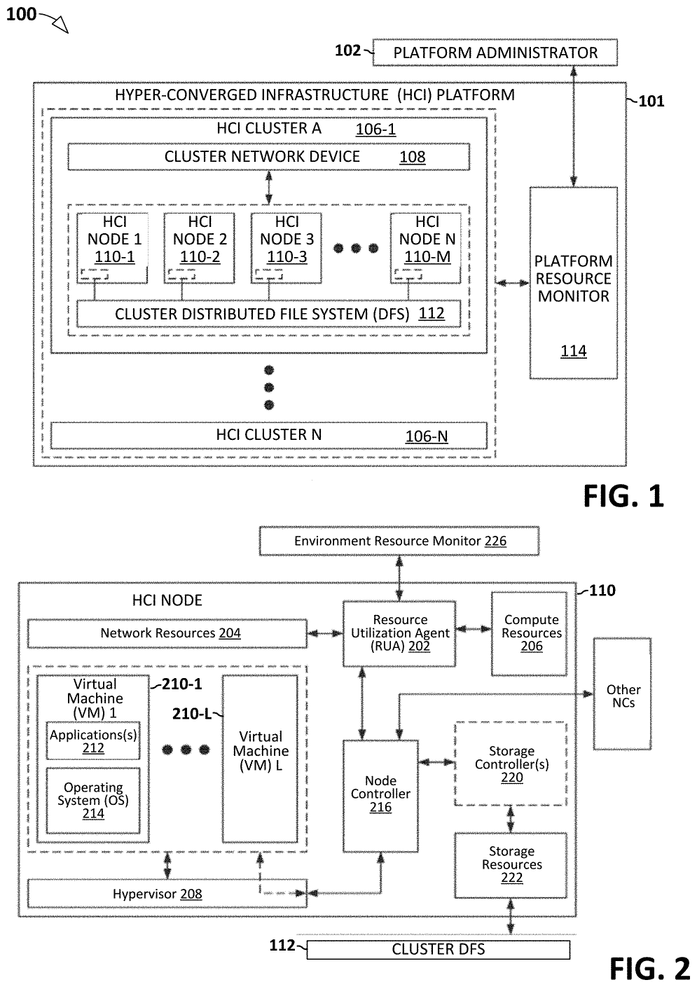

Exemplary embodiments and their advantages are best understood by reference to FIGS. 1-6, wherein like numbers are used to indicate like and corresponding parts unless expressly indicated otherwise.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

Additionally, an information handling system may include firmware for controlling and/or communicating with, for example, hard drives, network circuitry, memory devices, I/O devices, and other peripheral devices. For example, the hypervisor and/or other components may comprise firmware. As used in this disclosure, firmware includes software embedded in an information handling system component used to perform predefined tasks. Firmware is commonly stored in non-volatile memory, or memory that does not lose stored data upon the loss of power. In certain embodiments, firmware associated with an information handling system component is stored in non-volatile memory that is accessible to one or more information handling system components. In the same or alternative embodiments, firmware associated with an information handling system component is stored in non-volatile memory that is dedicated to and comprises part of that component.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

In the following description, details are set forth by way of example to facilitate discussion of the disclosed subject matter. It should be apparent to a person of ordinary skill in the field, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically. Thus, for example, “device 12-1” refers to an instance of a device class, which may be referred to collectively as “devices 12” and any one of which may be referred to generically as “a device 12”.

As used herein, when two or more elements are referred to as “coupled” to one another, such term indicates that such two or more elements are in electronic communication, mechanical communication, including thermal and fluidic communication, thermal, communication or mechanical communication, as applicable, whether connected indirectly or directly, with or without intervening elements.

Before describing disclosed features for monitoring and managing event messages in a distributed computing environment, an exemplary HCI platform suitable for implementing these features is provided. Referring now to the drawings, FIG. 1 and FIG. 2 illustrate an exemplary information handling system 100. The information handling system 100 illustrated in FIG. 1 and FIG. 2 includes a platform 101 communicatively coupled to a platform administrator 102. The platform 101 illustrated in FIG. 1 is an HCI platform in which compute, storage, and networking resources are virtualized to provide a software defined information technology (IT) infrastructure. Administrator 102 may be any computing system with functionality for overseeing operations and maintenance pertinent to the hardware, software, and/or firmware elements of HCI platform 101. Platform administrator 102 may interact with HCI platform 101 via requests to and responses from an application programming interface (API) (not explicitly depicted). In such embodiments, the requests may pertain to event messaging monitoring and event messaging state management described below. The HCI platform 101 illustrated in FIG. 1 may be implemented as or within a data center and/or a cloud computing resource featuring software-defined integration and virtualization of various information handling resources including, without limitation, servers, storage, networking resources, management resources, etc.

The HCI platform 101 illustrated in FIG. 1 includes one or more HCI clusters 106-1 through 106-N communicatively coupled to one another and to a platform resource monitor (PRM) 114. Each HCI cluster 106 illustrated in FIG. 1 encompasses a group of HCI nodes 110-1 through 110-M configured to share information handling resources. In some embodiments, resource sharing may entail virtualizing a resource in each HCI node 110 to create a logical pool of that resource, which, subsequently, may be provisioned, as needed, across all HCI nodes 110 in HCI cluster 106. For example, when considering storage resources, the physical device(s) (e.g., hard disk drives (HDDs), solid state drives (SSDs), etc.) representative of the local storage resources on each HCI node 110 may be virtualized to form a cluster distributed file system (DFS) 112. In at least some such embodiments, cluster DFS 112 corresponds to a logical pool of storage capacity formed from some or all storage within an HCI cluster 106.

An HCI cluster 106, and the one or more HCI nodes 110 within the cluster, may represent or correspond to an entire application or to one or more of a plurality of micro services that implement the application. As an example, an HCI cluster 106 may be dedicated to a specific micro service in which multiple HCI nodes 110 provide redundancy and support high availability. In another example, the HCI nodes 110 within HCI cluster 106 include one or more nodes corresponding to each micro service associated with a particular application.

The HCI cluster 106-1 illustrated in FIG. 1 further includes a cluster network device (CND) 108, which facilitates communications and/or information exchange between the HCI nodes 110 of HCI cluster 106-1 and other clusters 106, PRM 114, and/or one or more external entities including, as an example, platform the administrator 102. In at least some embodiments, CND 108 is implemented as a physical device, examples of which include, but are not limited to, a network switch, a network router, a network gateway, a network bridge, or any combination thereof.

PRM 114 may be implemented with one or more servers, each of which may correspond to a physical server in a data center, a cloud-based virtual server, or a combination thereof. PRM 114 may be communicatively coupled to all HCI nodes 110 across all HCI clusters 106 in HCI platform 101 and to platform administrator 102. PRM 114 may include a resource utilization monitoring (RUM) service or feature with functionality to monitor resource utilization parameters (RUPs) associated with HCI platform 101.

FIG. 2 illustrates an exemplary HCI node 110 in accordance with disclosed subject matter. HCI node 110, which may be implemented with a physical appliance, e.g., a server (not shown), implements hyper-convergent architecture, offering the integration of virtualization, compute, storage, and networking resources into a single solution. HCI node 110 may include a resource utilization agent (RUA) 202 communicatively coupled to network resources 204, compute resources 206, and a node controller 216. The node controller 216 illustrated in FIG. 2 is coupled to a hypervisor 208 that supports one or more virtual machines (VMs) 210-1 through 210-L), each of which is illustrated with an operating system (OS) 214 and one or more application program(s) 212. The illustrated node controller 216 is further coupled to storage components including zero or more optional storage controllers 220, for example, a small computer system interface (SCSI) controller, and storage components 222.

In some embodiments, RUA 202 is tasked with monitoring the utilization of virtualization, compute, storage, and/or network resources on HCI node 110. Thus, the node RUA 202 may include functionality to: monitor the utilization of: network resources 204 to obtain network resource utilization parameters (RUPs), compute resources 206 to obtain compute RUPs, virtual machines 210 to obtain virtualization RUPs, storage resources 222 to obtain storage RUPs. RUA 202 may provide some or all RUPs to environment resource monitor (ERM) 226 periodically through pull and/or push mechanisms.

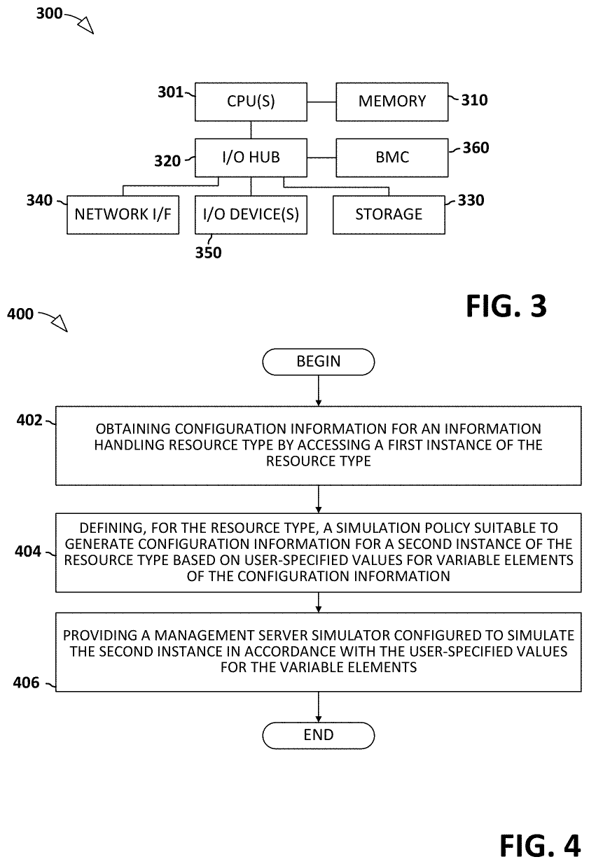

Referring now to FIG. 3, one or more of the HCI nodes described herein may be instantiated as physical nodes exemplified by the information handling system 300 illustrated in FIG. 3. The illustrated information handling system include one or more general purpose processors or central processing units (CPUs) 301 communicatively coupled to a memory resource 310 and to an input/output hub 320 to which various I/O resources and/or components are communicatively coupled. The I/O resources explicitly depicted in FIG. 3 include a network interface 340, commonly referred to as a NIC (network interface card), storage resources 330, and additional I/O devices, components, or resources including as non-limiting examples, keyboards, mice, displays, printers, speakers, microphones, etc. The illustrated information handling system 300 includes a baseboard management controller (BMC) 360 providing, among other features and services, an out-of-band management resource which may be coupled to a management server (not depicted). In at least some embodiments, BMC 360 may manage information handling system 300 even when information handling system 300 is powered off or powered to a standby state. BMC 360 may include a processor, memory, an out-of-band network interface separate from and physically isolated from an in-band network interface of information handling system 300, and/or other embedded information handling resources. In certain embodiments, BMC 360 may include or may be an integral part of a remote access controller (e.g., a Dell Remote Access Controller or Integrated Dell Remote Access Controller) or a chassis management controller.

Referring now to FIG. 4, a flow diagram illustrates a HCI platform development method 400 to address and resolve at least platform development issues associated with developing platforms to support a wide variety of hardware resources that may not be physically available to platform developers. The illustrated method 400 begins by obtaining (operation 402) configuration information for an information handling resource type, such as a storage device, a NIC, a CPU, etc. The configuration information may be obtained by accessing a first instance of the resource type. In this context, the first instance of a resource type may be a resource physically present on the node.

In at least one embodiment, the configuration information includes one or more attribute-value pairs or another similar data structure, each of which includes a fixed element, indicated in the name field, and a variable element, indicated in the value field of the pair. As an illustrative example, configuration information for a NIC type may include a set of three attribute-value pairs identifying a vendor, model, and firmware version of the NIC. Although a NIC's state and configuration may not be fully described by these three parameters, these parameters may represent all NIC configuration information consumer and/or required by higher level programs. Each of the three attribute-value pairs would include information in the appropriate value field, identifying the vendor, make, and firmware version. In this example, the fixed portion of the configuration information includes the information indicated in the name field of each attribute-value pair, i.e., vendor, model, and firmware version, while the variable information is the information included in the value field of each attribute-value pair. An example for a NIC might be Qlogic, Intel, and 20.11.16 where Qlogic is the vendor, Intel is the model, and 20.11.16 indicates the firmware version.

The method 400 illustrated in FIG. 2 then defines (operation 404) a simulation policy for the resource type. The simulation policy supports and/or enables a simulator to generate configuration information for a second instance of the resource type based on user-specified values for the variable elements of the configuration information. For example, the simulator policy may associate each fixed part of the configuration information for a NIC type (e.g., vendor, model, firmware version) with variable part information that differs from the variable information in the first instance of the resource type. Support for instances of resource types that are not physically present within the applicable system and not readily available at a reasonable price is enabled by a management server simulator configured to access the simulator policy associated with a particular resource type to retrieve the fixed part of the resource type's configuration information and inject user-specified information for the variable part of the configuration information.

Thus, the illustrated method 400 provides (operation 406) a management server simulator to simulate a second instance of the resource type in accordance with the resource type's configuration parameters. The management server simulator may identify configuration parameters appropriate for the particular resource type from the fixed parts of configuration information obtained from an existing instance of a resource type, and simulate the presence of a different instance of the resource type and, most beneficially, the presence of a resource type instance that is not available to the platform developer by injecting user-specified information for the variable parts of the configuration information.

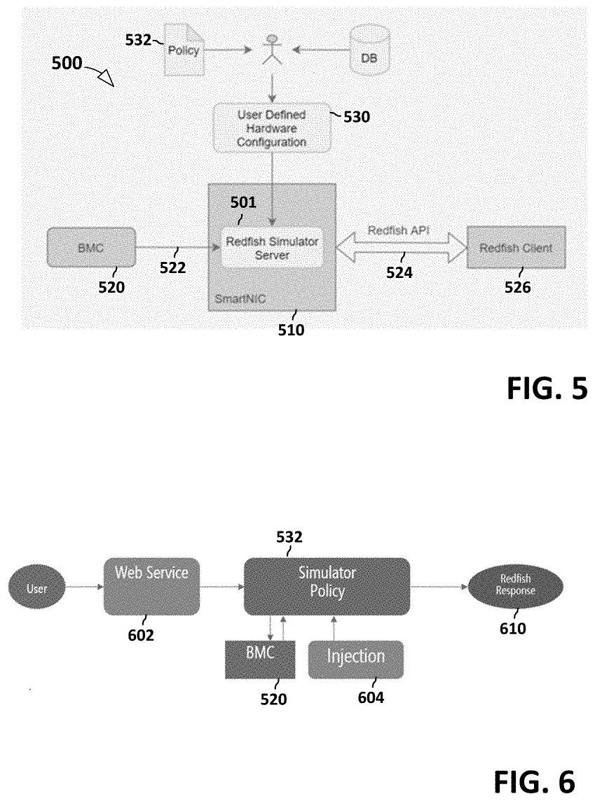

Turning now to FIG. 5 and FIG. 6, hardware and software components of at least one embodiment of a management server simulator suitable for performing the method 400 illustrated in FIG. 4 and described in the preceding description of FIG. 4. FIG. 5 illustrates a node 500, which may be functionally and/or structurally analogous to one or more of the nodes 110 illustrated in FIG. 1 and FIG. 2, in which a Redfish server simulator 501 is provided as application software executing on a SmartNIC 510. SmartNIC 510 is a programmable network adapter card with programmable accelerators and Ethernet connectivity that can accelerate infrastructure applications. The depicted SmartNIC 510 is communicatively coupled to a BMC 520. In at least one embodiment, SmartNIC 510 and BMC 520 are both installed on physical node 500 and configured to communicate with one another via a network connection 522, which may be an in-band network connection or an out-of-band network connection.

Redfish simulator server 501 includes and/or exposes one or more Redfish APIs 524. The one or more Redfish APIs 524 may be configured to accept user input indicative of a user-defined hardware configuration, which may be referred to herein as a “mocked” hardware configuration. In it least some embodiments, when a Redfish client 526 accesses Redfish server simulator 501 via Redfish APIs 524, the access is “hooked” by user-defined hardware configuration information 530. Redfish server simulator 501 may be configured to recognize the resource type, e.g., from information included in a request from Redfish client 526, and access a simulation policy 532 for the applicable resource type. The simulation policy for the applicable resource type may identify the fixed part of the configuration information and the Redfish server simulator 501 may then replace variable parts of the configuration with user specified values.

FIG. 6 illustrates interaction among various software components of the node 500. As depicted in FIG. 6, a web service 602 provided by Redfish server simulator 501 (FIG. 5) accesses simulation policy 532 based on the applicable fixed-part configuration information, which may be provided by BMC 520, and injected information 604 which may include user-specified hardware configuration information. Based on the simulation policy 532 and the injected data 604, Redfish server simulator 501 generates a simulated Redfish response 610. The simulated response 610 is preferably the same or substantially similar to a response that would have been provided by a Redfish server on a physical node in which an actual instance of simulated resource was installed.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A platform development method, comprising:
obtaining configuration information for an information handling resource type by accessing a first instance of the resource type, wherein the configuration information includes one or more fixed elements and one or more corresponding variable elements;
defining a simulation policy for the resource type, wherein the simulation policy is suitable to generate configuration information for a second instance of the resource type based on user-specified values for the variable elements of the configuration information; and
providing a management server simulator configured to simulate the second instance in accordance with the user-specified values for the variable elements.

2. The platform development method of claim 1, wherein obtaining the configuration information includes obtaining the information from a baseboard management controller (BMC) communicatively coupled to the first instance of the information handling resource type.

3. The platform development method of claim 1, wherein the information handling resource type comprises one of a plurality of information handling resource types, wherein the plurality of information handling resource types include a network interface card (NIC) type, a storage device type, and a central processing unit (CPU) type.

4. The platform development method of claim 1, wherein the configuration information includes one or more attribute-value pairs, wherein each attribute-value pair includes a name field indicative of a configuration parameter and a value field indicative of a configuration parameter value.

5. The platform development method of claim 4, wherein the name field corresponds to the fixed element and the value field corresponds to the variable element.

6. The platform development method of claim 1, wherein the management server simulator comprises a Redfish simulator configured to provide Redfish services.

7. The platform development method of claim 6, wherein the Redfish simulator includes one or more simulator application programming interfaces (APIs) configured to receive requests from a Redfish client and inject user-specified values for the variable elements into responses provided to the Redfish client.

8. The platform development method of claim 1, wherein the management server simulator is implemented in a SmartNIC.

9. The platform development method of claim 8, wherein the SmartNIC is installed on a physical node and communicatively coupled to a baseboard management controller.

10. An information handling system, comprising:
a central processing unit (CPU);
one or more storage resources including processor-executable program instructions that, when executed by the CPU, cause the information handling system to perform platform development operations, wherein the operations include:
obtaining configuration information for an information handling resource type by accessing a first instance of the resource type, wherein the configuration information includes one or more fixed elements and one or more corresponding variable elements;
defining a simulation policy for the resource type, wherein the simulation policy is suitable to generate configuration information for a second instance of the resource type based on user-specified values for the variable elements of the configuration information; and
providing a management server simulator configured to simulate the second instance in accordance with the user-specified values for the variable elements.

11. The information handling system of claim 10, wherein obtaining the configuration information includes obtaining the information from a baseboard management controller (BMC) communicatively coupled to the first instance of the information handling resource type.

12. The information handling system of claim 10, wherein the information handling resource type comprises one of a plurality of information handling resource types, wherein the plurality of information handling resource types include a network interface card (NIC) type, a storage device type, and a central processing unit (CPU) type.

13. The information handling system of claim 10, wherein the configuration information includes one or more attribute-value pairs, wherein each attribute-value pair includes a name field indicative of a configuration parameter and a value field indicative of a configuration parameter value.

14. The information handling system of claim 13, wherein the name field corresponds to the fixed element and the value field corresponds to the variable element.

15. The information handling system of claim 10, wherein the management server simulator comprises a Redfish simulator configured to provide Redfish services.

16. The information handling system of claim 15, wherein the Redfish simulator includes one or more simulator application programming interfaces (APIs) configured to receive requests from a Redfish client and inject user-specified values for the variable elements into responses provided to the Redfish client.

17. The information handling system of claim 10, wherein the management server simulator is implemented in a SmartNIC.

18. The information handling system of claim 17, wherein the SmartNIC is installed on a physical node and communicatively coupled to a baseboard management controller.
